(19) United States
(12) Patent Application Publication
(10) Pub. No.: US 2023/0223790 A1
(43) Pub. Date: Jul. 13, 2023

(54) NON-CONTACT POWER RECEPTION DEVICE AND METHOD

(71) Applicant: LAPIS Technology Co., Ltd., Yokohama (JP)

(72) Inventor: Koki NAKANISHI, Yokohama (JP)

(73) Assignee: LAPIS Technology Co., Ltd., Yokohama (JP)

(21) Appl. No.: 18/153,089

(22) Filed: Jan. 11, 2023

(30) Foreign Application Priority Data
Jan. 11, 2022 (JP) 2022-002129

(51) Int. Cl. H02J 50/12; G01R 33/36; H02J 50/70

(52) U.S. Cl. CPC H02J 50/12; G01R 33/3628; H02J 50/70

(57) ABSTRACT

A power reception device includes a power reception control circuit connected to respective terminals of a power reception coil and receiving power supply by a voltage generated between the respective terminals due to a magnetic field, a matching capacitor connected in parallel with the respective terminals of the power reception coil, and a switching element connected in series with the capacitor and connected to the power reception control circuit. The power reception control circuit includes: a detection unit that detects a change in the power reception control circuit in accordance with a change in intensity of a magnetic field received by the power reception coil; and a switch adjustment unit that adjusts a state of the switching element when the detection unit detects a change that is equal to or greater than a prescribed degree.

### CROSS REFERENCE TO RELATED APPLICATION

This application is based upon and claims the benefit of priority of the prior Japanese Patent Application No. 2022-002129, filed on Jan. 11, 2022, the entire contents of which are incorporated herein by reference.

### TECHNICAL FIELD

The present invention relates to a power reception device and a method that receive power from a power transmission device in a non-contact manner.

### BACKGROUND ART

A non-contact power supply system is a technology for transmitting power from a power transmission device to a power reception device in a non-contact manner using an electromagnetic field as a medium. While this technology improves the flexibility and convenience of all electronic devices, there are some concerns for power transmission in space. Those concerns include changes in the intensity of the electromagnetic field due to changes in the distance of power transmission and reception. When an electronic device including a power reception device is exposed to an excessive magnetic field, a voltage exceeding the specifications of the power reception device is generated inside the device, which causes a problem of a breakdown of the electronic device.

Conventional safeguards against this problem include fuses and Zener diodes. A fuse, however, has the drawback of being irreversible once blown, and that it has a very high impedance when protected and generates a high voltage. Zener diodes can dissipate excess power by allowing current to flow, but they have the drawback of generating a large amount of heat.

In addition, in a non-contact power supply system, there is a known technique for a power reception device where a transistor is turned on to stop power supply from a power reception coil to an output unit when a power reception circuit receives power of a prescribed level or greater (see WO2018/037758).

### SUMMARY OF THE INVENTION

### Problems to be Solved by the Invention

In the prior art, however, because the power supply stops when power is received, the power supply required for the operation of the device also stops, which poses a problem.

The present invention was made in view of the above-described problem in the prior art, and an object thereof is to provide a power reception device that does not cause a breakdown of an electronic device or stoppage of wireless power supply even when the power reception device is exposed to an excessive amount of electromagnetic field.

A power reception device of the present invention includes: a power reception coil; a power reception control circuit connected to respective terminals of the power reception coil and receiving power supply by a voltage generated between the respective terminals due to a magnetic field; a matching capacitor connected in parallel with the respective terminals of the power reception coil; and a switching element connected in series with the matching capacitor and connected to the power reception control circuit, wherein the power reception control circuit includes: a detection unit that detects a change that occurs in the power reception control circuit in accordance with a change in intensity of a magnetic field received by the power reception coil; and a switch adjustment unit that adjusts a state of the switching element when the detection unit detects a change that is equal to or greater than a prescribed degree.

A power reception method of the present invention is a power reception method for a non-contact power reception device that includes a power reception coil; a power reception control circuit connected to respective terminals of the power reception coil and receiving power supply by a voltage generated between the respective terminals due to a magnetic field; a matching capacitor connected in parallel with the respective terminals of the power reception coil; and a switching element connected in series with the matching capacitor and connected to the power reception control circuit, the method including: a detection step of detecting a change that occurs in the power reception control circuit in accordance with a change in intensity of a magnetic field received by the power reception coil; and a switch adjusting step of adjusting a state of the switching element to one state when a change equal to or greater than a prescribed degree is detected, and adjusting the state of the switching element to a state differing from the one state when a change that is smaller than a prescribed degree is detected; and a holding step of holding the state of the switching element.

According to the present invention, it is possible to achieve a beneficial effect of preventing a breakdown of a device due to supply of an excessive amount of power, without stopping the operation of a power reception device.

### BRIEF DESCRIPTION OF THE DRAWINGS

FIG. 1 is a block diagram of a non-contact power supply system including a power reception device of Embodiment 1.

FIG. 2 is a timing chart explaining the operation of the power reception device of Embodiment 1.

FIG. 3 is a block diagram of a non-contact power supply system including a power reception device of Embodiment 2.

FIG. 4 is a block diagram of a non-contact power supply system including a power reception device of Embodiment 3.

### DETAILED DESCRIPTION OF EMBODIMENTS

Embodiments of the present invention will be explained below in detail with reference to the drawings. In the respective embodiments, constituting elements having substantially the same function or configuration are given the same reference characters, and the descriptions thereof will not be repeated.

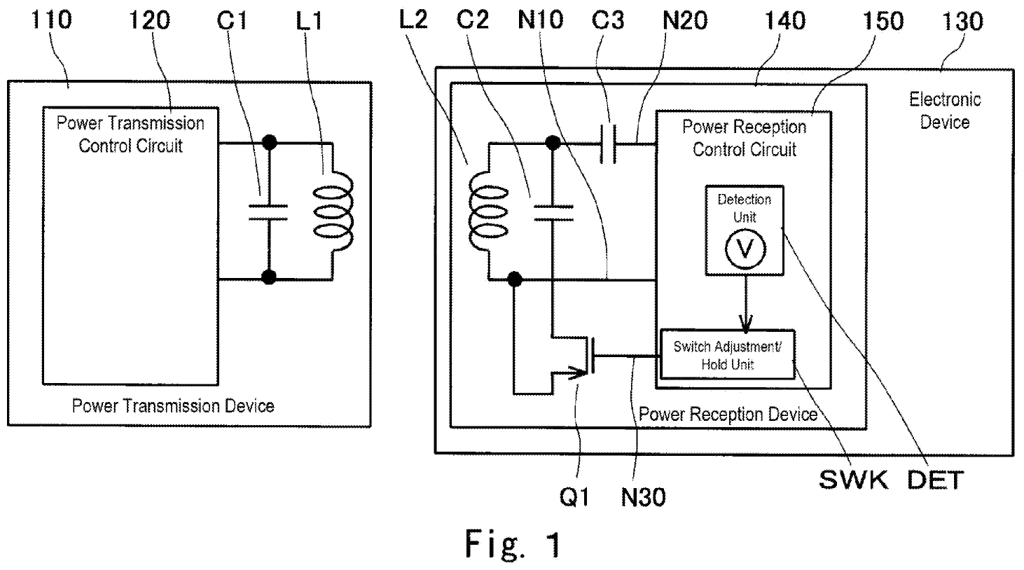

FIG. 1 is a block diagram illustrating an example of a non-contact power supply system including a power transmission device 110 and a power reception device 140 of an embodiment of the present invention.

The power transmission device 110 on the power transmission side includes a power transmission control circuit 120, an antenna coil L1, a capacitor C1, and the like, for example.

An electronic device 130 on the power reception side includes a power reception device 130, a power reception control circuit 150, an antenna coil L2, a capacitor C2, a battery, and the like, for example. However, in FIG. 1, the battery connected to the power reception control circuit 150 is not shown, and a rectifier circuit of the power reception control circuit 150 or a charging circuit for the battery is not shown either.

The power transmission control circuit 120 applies an AC voltage to the antenna coil L1 and the capacitor C1 to generate an AC magnetic field at the antenna coil. The antenna coil L1 of the power transmission device 110 relays this AC electromagnetic field to the antenna coil L2 that receives power in the power reception device 140. This AC magnetic field causes magnetic field coupling with the antenna coil L2 of the power reception device 140, and due to the resultant electromotive force, power is supplied to the power reception control circuit 150.

The capacitors C1 and C2 used in the power transmission device 110 and the power reception device 140, respectively, are connected to adjust the impedance matching, and by selecting an appropriate capacitance value, it is possible to supply power from the power transmission device 110 to the power reception device 140 efficiently.

### Embodiment 1

In the power reception device 140 of Embodiment 1, the power reception control circuit 150 causes the switch adjustment unit SWK to operate a semiconductor switch of the switching element connected in series with the capacitor C2 so that the capacitor C2 connected in parallel with the antenna coil L2, which is a power reception coil, functions as a protection circuit. For the semiconductor switch of the switching element, an NMOS transistor Q1 in which the drain terminal and the source terminal thereof are connected to a resonance circuit (L2, C2) is used, for example.

The power reception control circuit 150 of the power reception device 140 of this embodiment includes a detection unit DET that detects an electromagnetic field received by the antenna coil L2, and when the detection unit DET detects an electromagnetic field having a prescribed intensity or greater, the switch adjustment unit SWK changes the ON/OFF state of the NMOS transistor Q1 accordingly.

The switch adjustment unit SWK changes the gate voltage level of the NMOS transistor Q1 to change the ON/OFF state of the NMOS transistor Q1 when the detection unit DET detects an electromagnetic field having a prescribed intensity or greater, thereby changing the impedance matching of the resonance circuit constituted of the power reception coil L2 and the matching capacitor C2.

The protection circuit is configured by inserting the drain and source of the NMOS transistor Q1 between the capacitor C2 and a node N10 of the power reception device 140. The gate of the NMOS transistor Q1 is connected to the switch adjustment unit SWK of the power reception control circuit 150 via a node N30. Furthermore, a second matching capacitor C3 is connected in series with a node N20 between the antenna coil L2 and the power reception control circuit 150.

The detection unit DET is a voltmeter connected to the node N10 or the node N20, for example, and detects a change in antenna terminal voltage measured by this voltmeter, and drives the switch adjustment unit SWK in accordance with the detection result.

### (Description of the Operation)

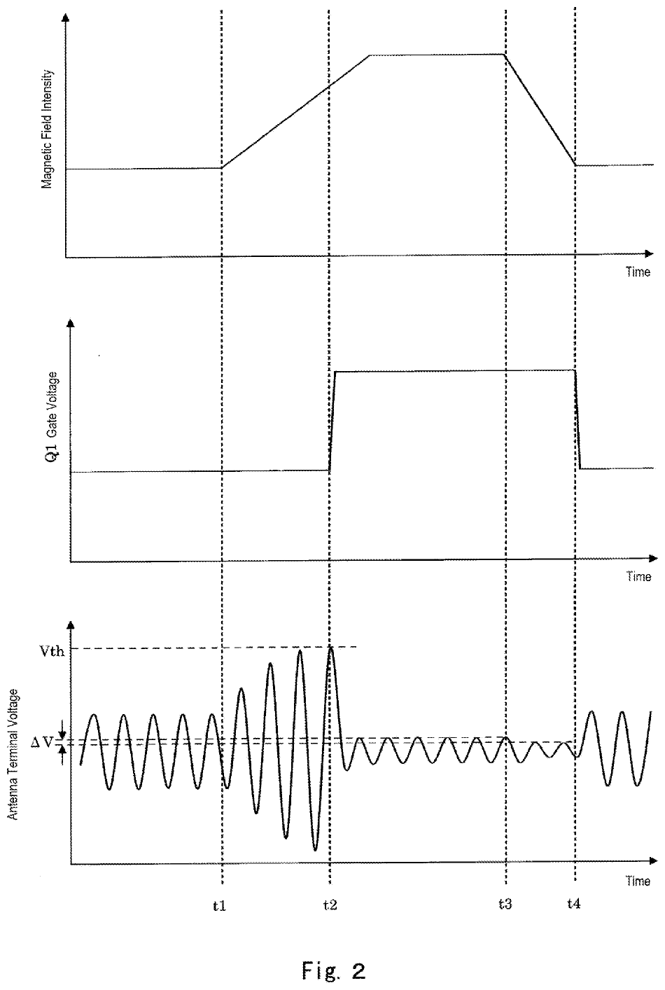

The operation of the non-contact power supply system illustrated in FIG. 1 will be explained with reference to the timing chart of FIG. 2.

When an AC magnetic field is applied to the antenna coil L2 of the power reception device, an AC voltage is induced at the node N10 and the node N20 at the respective ends of the antenna coil L2. This AC voltage is inputted to the power reception control circuit 150, and undergoes DC conversion, signal processing, and the like in the device. At this time, the gate voltage of the NMOS transistor Q1 is at a low level, and the NMOS transistor Q1 is off. This means that the capacitor C2 and the antenna coil L2 are separated, and do not contribute to matching (up until time t1 of the timing chart of FIG. 2).

When the magnetic field being applied becomes excessive, the amplitude of the voltage generated at the respective ends of the antenna coil L2 of the power reception device increases. Then, when the detection unit DET of the power reception control circuit 150 detects a voltage (Vth) corresponding an electromagnetic field having a prescribed intensity or greater, the switch adjustment unit SWK raises the gate voltage of the NMOS transistor Q1 to a high level (time t2 in the timing chart of FIG. 2). This causes the capacitor C2 to be connected with the antenna coil L2 in parallel, and it is therefore possible to change the impedance matching. By increasing the impedance matching, the power reception device 140 can avoid receiving excessive power, and because the device will not receive an input of a voltage greater than a standard value, a breakdown of the device is prevented.

While this protection operation blocks excessive power, the device continues to receive minimal power necessary for the operation of the electronic device 130, and thus, the electronic device 130 will not shut down due to power outage (from time t2 onward in the timing chart of FIG. 2). Thus, even if power received is lowered due to this protection operation, the protection operation does not stop immediately, and the switch adjustment unit SWK maintains the low-power supply state (between time t2 and time t3 in the timing chart of FIG. 2). The switch adjustment unit SWK maintains the ON state or the OFF state of the switching element as long as the detection unit DET keeps detecting an electromagnetic field having a prescribed intensity or greater.

Thereafter, when the magnetic field being applied decreases, (between time t3 and time t4 in the timing chart of FIG. 2), the amplitude of the voltage generated at the respective ends of the antenna coil L2 of the power reception device lowers (ΔV). Then, when the detection unit DET of the power reception control circuit 150 detects this voltage drop, the switch adjustment unit SWK lowers the gate voltage of the NMOS transistor Q1 to a low level (time t4 in the timing chart of FIG. 2). This restores the power supply state (from time t4 onward in the timing chart of FIG. 2)

### (Description of the Effects)

As descried above, according to this embodiment, because the NMOS transistor Q1 is connected to the capacitor C2 for the matching adjustment control, even when the electronic device 130 including the power reception device 140 is exposed to an excessive magnetic field, it is possible to keep the power to be received at a low level so that a voltage exceeding a prescribed standard will not be applied to the device, which prevents a breakdown of the electronic device 130.

In this embodiment, one matching capacitor is connected in series, and one matching capacitor is connected in parallel, but this configuration is merely an example, and this control is possible with any other combinations of matching capacitors.

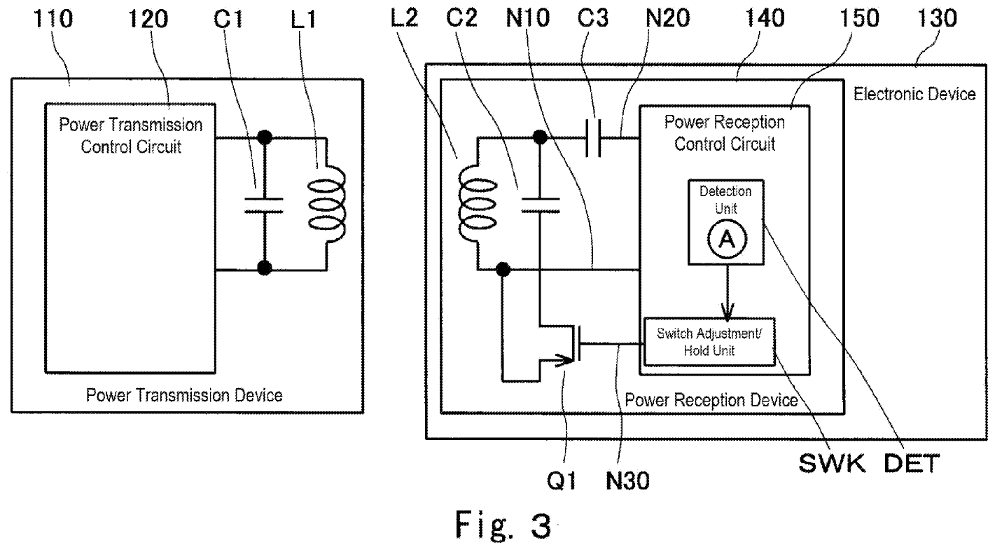

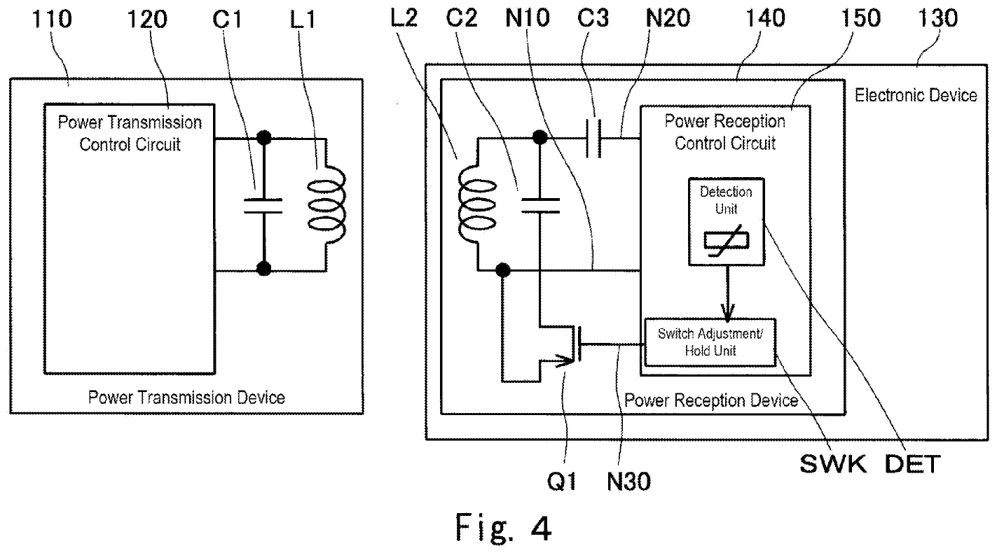

In this embodiment, the detection unit DET is a voltmeter connected to the node N10 or the node N20, but instead, it is possible to use an ampere meter for the detection unit DET as illustrated in FIG. 3 (Embodiment 2). In this case, a change in magnetic field received by the antenna coil L2 is detected as a change in current, and the switch adjustment unit SWK is driven based on the detection result. Furthermore, as Embodiment 3 illustrated in FIG. 4, a thermometer such as a thermistor placed near the rectifier circuit (not shown in the figure) may be used for the detection unit DET. In this case, a change in magnetic field received by the antenna coil L2 is detected as a change in temperature, and the switch adjustment unit SWK is driven based on the detection unit.

In the foregoing description, impedance matching was adjusted in a way that the gate voltage of the NMOS transistor Q1 is set to a low level during the normal operation, and is set to a high level during the protection operation, but it is also possible to set the gate voltage to a high level during the normal operation, and to a low level during the protection operation.

As described above, in this embodiment, the power reception device 140 is configured such that the drain and source of the NMOS transistor Q1 are connected between the matching capacitor C2 and the node N10, the gate is connected to the power reception control circuit 150 that has the detection unit DET detecting an excessive magnetic field and the switch adjustment unit SWK, the switch adjusting unit SWK changes the gate voltage level during the protection operation to switch on or off the NMOS transistor, and the impedance matching of the resonance circuit is changed such that the induced voltage level inputted into the power reception device 140 is suppressed. As a result, a breakdown of an electronic device is prevented. The switch adjustment unit SWK maintains the protection operation state as long as the magnetic field remains excessive.

The power reception device 140 can be installed in an NFC communication device (not shown in the figure) that is capable of transmitting and receiving data as well as charging a battery (not shown in the figure) through non-contact power supply, using the antenna coil L2 as a common antenna for communication.

The power reception device 140 may also include a rectifier circuit, a charging circuit, and the like connected in a certain order, in addition to the antenna coil L2. The power reception device 140 may also include a communication circuit to be used for a smartphone, for example. In this embodiment, the level of the start-up voltage of the power reception device 140 is low, and thus, it is preferable to use an NMOS transistor for the switching element as the gate thereof has a low threshold voltage.

What is claimed is:

1. A power reception device, comprising:
a power reception coil;
a power reception control circuit connected to respective terminals of the power reception coil and receiving power supply by a voltage generated between the respective terminals due to a magnetic field;
a matching capacitor connected in parallel with the respective terminals of the power reception coil; and
a switching element connected in series with the matching capacitor and connected to the power reception control circuit,
wherein the power reception control circuit includes:
a detection unit that detects a change that occurs in the power reception control circuit in accordance with a change in intensity of a magnetic field received by the power reception coil; and
a switch adjustment unit that adjusts a state of the switching element when the detection unit detects a change that is equal to or greater than a prescribed degree.

2. The power reception device according to claim 1, wherein, after adjusting the state of the switching element, the switch adjustment unit maintains the state of the switching element as long as the detection unit keeps detecting the change that is equal to or greater than the prescribed degree.

3. The power reception device according to claim 2, wherein, after adjusting the state of the switching element, the switch adjustment unit adjusts back the state of the switching element when the detection unit detects a change that is smaller than the prescribed degree.

4. The power reception device according to claim 1, wherein the detection unit is one of a voltmeter that detects the voltage between the respective terminals of the power reception coil, an ampere meter that detects a current between the respective terminals, or a thermometer, and
wherein the switch adjustment unit detects a change in voltage, current, or temperature detected by the voltmeter, ampere meter, or thermometer as a change that occurs in the power reception control circuit due to the change in intensity of the magnetic field received by the power reception coil.

5. The power reception device according to claim 4, wherein the detection unit is a voltmeter, and the switch adjustment unit changes the state of the switching element when a voltage value of the voltmeter exceeds a prescribed amplitude.

6. The power reception device according to claim 5, wherein the switch adjustment unit changes back the state of the switching element when the voltage value of the voltmeter goes below the prescribed amplitude.

7. The power reception device according to claim 1, wherein the switching element is an NMOS transistor, and
wherein the switch adjustment unit changes a gate voltage level of the NMOS transistor to switch on or off the NMOS transistor when the detection unit detects an electromagnetic field having a prescribed intensity or greater, thereby changing impedance matching of a resonance circuit constituted of the power reception coil and the matching capacitor.

8. The power reception device according to claim 1, wherein the switch adjustment unit turns on the switching element when the detection unit detects the change that is equal to or greater than the prescribed degree.

9. A power reception method of a non-contact power reception device that includes a power reception coil, a power reception control circuit connected to respective terminals of the power reception coil and receiving power supply by a voltage generated between the respective terminals due to a magnetic field, a matching capacitor connected in parallel with the respective terminals of the power reception coil, and a switching element connected in series with the matching capacitor and connected to the power reception control circuit, the power reception method comprising:
a detection step of detecting a change that occurs in the power reception control circuit in accordance with a change in intensity of a magnetic field received by the power reception coil; and
a switch adjusting step of adjusting a state of the switching element to one state when a change equal to or greater than a prescribed degree is detected, and adjusting the state of the switching element to a state differing from said one state when a change smaller than a prescribed degree is detected; and
a holding step of holding the state of the switching element.
